(19) United States
(12) Patent Application Publication
(10) Pub. No.: US 2024/0341079 A1
(43) Pub. Date: Oct. 10, 2024

(54) WORDLINE RECESS FORMATION AND RESULTING STRUCTURES

(71) Applicant: Micron Technology, Inc., Boise, ID (US)

(72) Inventors: Babak Tahmouresilerd, Boise, ID (US); Ramaswamy Ishwar Venkatanarayanan, Boise, ID (US); Don Koun Lee, Boise, ID (US); Purnima Narayanan, Fremont, CA (US); Sanjeev Sapra, Boise, ID (US)

(21) Appl. No.: 18/600,324

(22) Filed: Mar. 8, 2024

Related U.S. Application Data
(60) Provisional application No. 63/457,295, filed on Apr. 5, 2023.

(51) Int. Cl. H10B 12/00

(52) U.S. Cl. CPC H10B 12/053; H10B 12/34

(57) ABSTRACT

Methods, systems, and devices for wordline recess formation and resulting structures are described. In some instances, aspects of a memory device may be formed using a wet etching process. For example, a wet etching process may be used to remove (e.g., etch) one or more materials (e.g., nitrides) when forming wordlines. The wet etching process may include depositing a first resist material and a second resist material to selectively remove (e.g., etch) different portions of the nitride material. Such processes may result in gate oxides of the memory device being relatively uniform in shape.

### CROSS REFERENCE

The present Application for Patent claims priority to and the benefit of U.S. Provisional Application No. 63/457,295 by Tahmouresilerd et al., entitled “WORDLINE RECESS FORMATION AND RESULTING STRUCTURES,” filed Apr. 5, 2023, assigned to the assignee hereof, and is expressly incorporated by reference in its entirety herein.

### TECHNICAL FIELD

The following relates to one or more systems for memory, including wordline recess formation and resulting structures.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports wordline recess formation and resulting structures in accordance with examples as disclosed herein.

FIGS. 2A through 2F show examples of processing steps that support wordline recess formation and resulting structures in accordance with examples as disclosed herein.

FIG. 3 shows a flowchart illustrating a method or methods that support wordline recess formation and resulting structures in accordance with examples as disclosed herein.

### DETAILED DESCRIPTION

A memory device (e.g., a DRAM device) may include wordlines configured to access one or more memory cells. In some cases, aspects of the memory device may be formed using a dry etching process. For example, a dry etching process may be used to remove (e.g., etch) one or more materials (e.g., nitrides) when forming the wordlines. The dry etching process may include depositing a resist material (e.g., a photoresist) to selectively remove (e.g., etch) different portions of the nitride material. However, the dry etching process may unintentionally affect the gate oxides of the memory device, which may negatively impact the device's overall performance. Using a dry etching process may result in the gate oxides being non-uniform, which may result in undesirable current loss when accessing an associated wordline. In some instances, such damage to the gate oxides may result in a portion (e.g., a die) of the memory device being discarded.

Methods for fabricating aspects of a memory device without unintentionally affecting gate oxides are described herein. In some instances, aspects of the memory device may be formed using a wet etching process. For example, a wet etching process may be used to remove (e.g., etch) one or more materials (e.g., nitrides) when forming wordlines. The wet etching process may include depositing a first resist material and a second resist material to selectively remove (e.g., etch) different portions of the nitride material. Such processes may result in gate oxides of the memory device being relatively uniform in shape, which may improve the device's overall performance. Moreover, having uniform gate oxides may mitigate undesirable current loss that may otherwise occur due to having non-uniform gate oxides, and may result in fewer portions (e.g., dice) of the memory device being discarded.

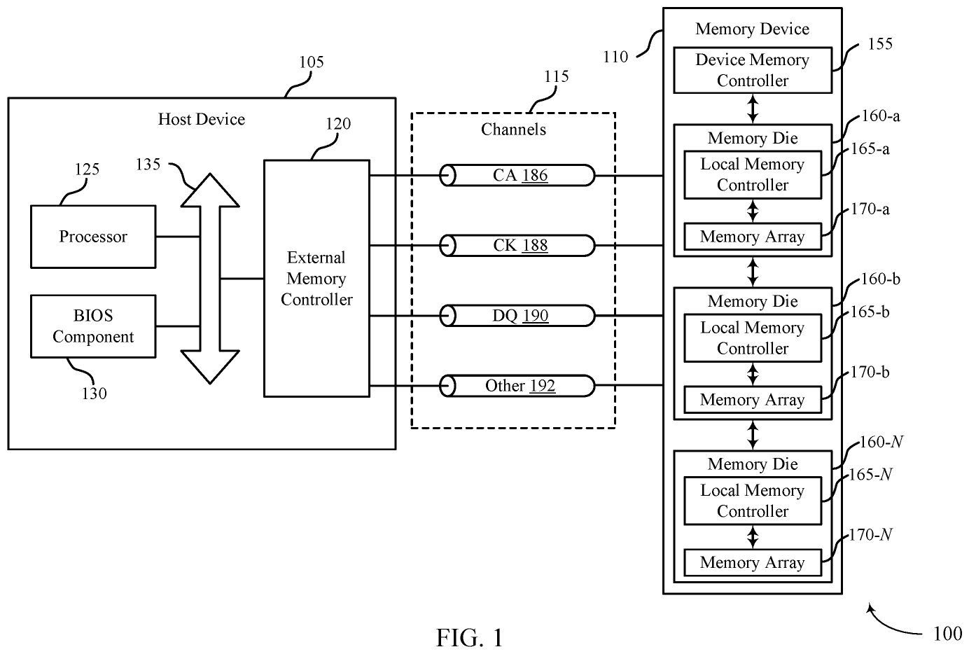

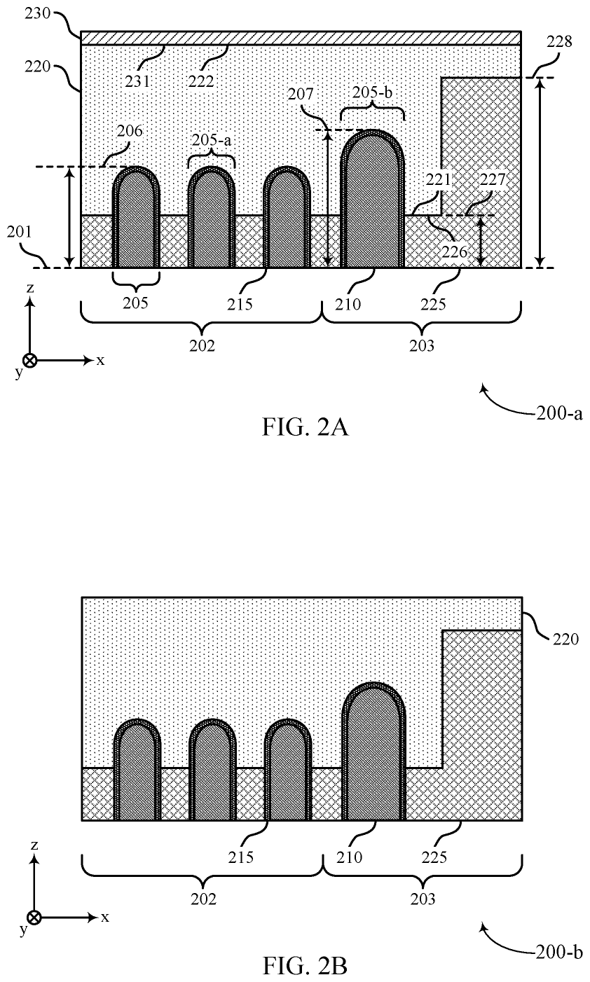

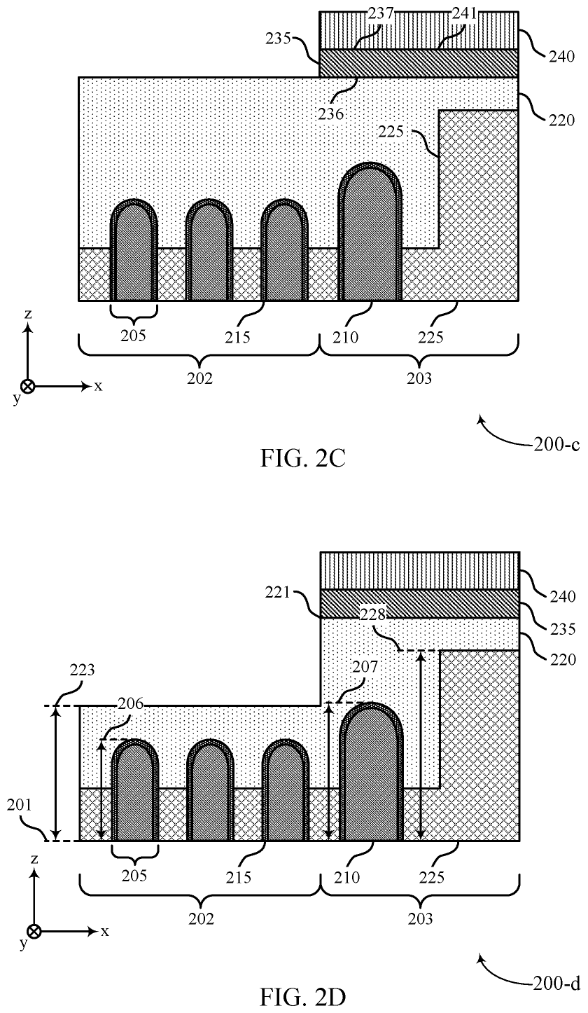

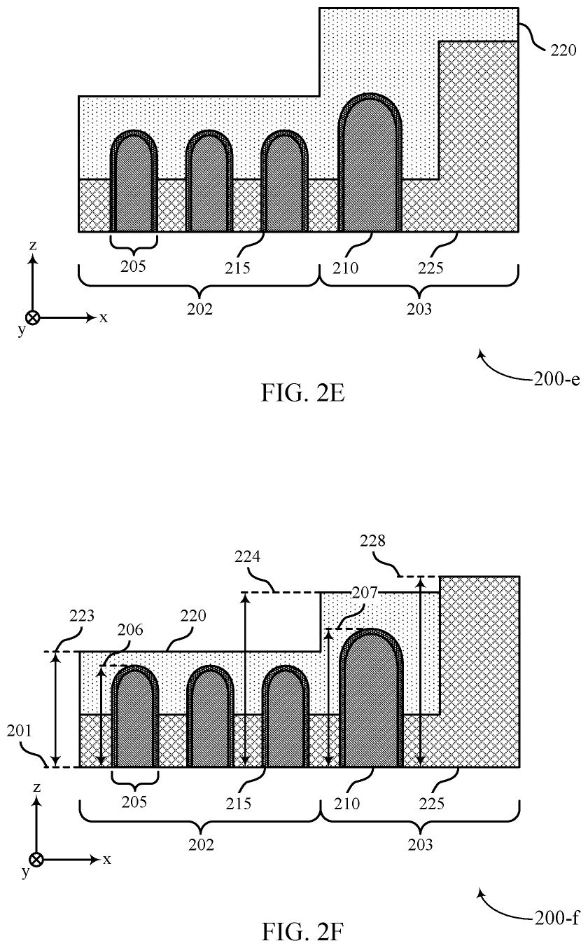

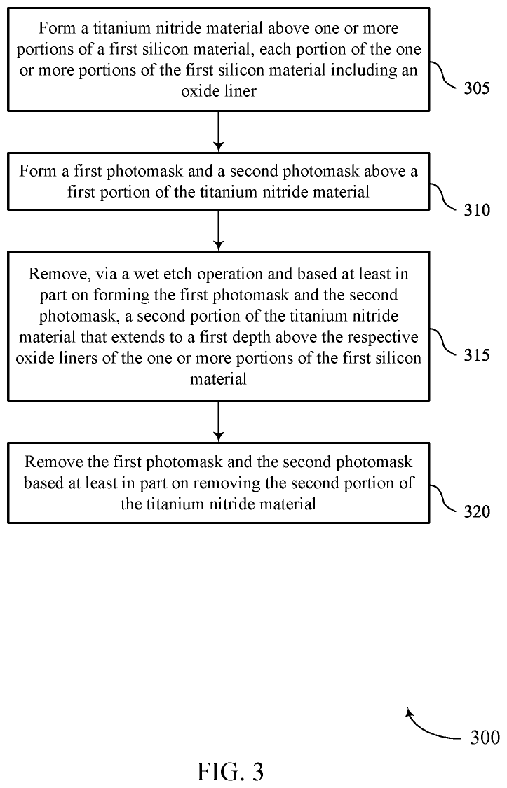

Features of the disclosure are described in the context of a system and processing steps as described with reference to FIGS. 1 through 2F. These and other features of the disclosure are further illustrated by and described with reference to a flowchart relating to wordline recess formation and resulting structures as described with reference to FIG. 3.

FIG. 1 shows an example of a system 100 that supports wordline recess formation and resulting structures in accordance with examples as disclosed herein. The system 100 may include a host device 105, a memory device 110, and a plurality of channels 115 coupling the host device 105 with the memory device 110. The system 100 may include one or more memory devices 110, but aspects of the one or more memory devices 110 may be described in the context of a single memory device (e.g., memory device 110).

The system 100 may include portions of an electronic device, such as a computing device, a mobile computing device, a wireless device, a graphics processing device, a vehicle, or other systems. For example, the system 100 may illustrate aspects of a computer, a laptop computer, a tablet computer, a smartphone, a cellular phone, a wearable device, an internet-connected device, a vehicle controller, or the like. The memory device 110 may be a component of the system 100 that is operable to store data for one or more other components of the system 100.

Portions of the system 100 may be examples of the host device 105. The host device 105 may be an example of a processor (e.g., circuitry, processing circuitry, a processing component) within a device that uses memory to execute processes, such as within a computing device, a mobile computing device, a wireless device, a graphics processing device, a computer, a laptop computer, a tablet computer, a smartphone, a cellular phone, a wearable device, an internet-connected device, a vehicle controller, a system on a chip (SoC), or some other stationary or portable electronic device, among other examples. In some examples, the host device 105 may refer to the hardware, firmware, software, or any combination thereof that implements the functions of an external memory controller 120. In some examples, the external memory controller 120 may be referred to as a host (e.g., host device 105).

A memory device 110 may be an independent device or a component that is operable to provide physical memory addresses/space that may be used or referenced by the system 100. In some examples, a memory device 110 may be configurable to work with one or more different types of host devices. Signaling between the host device 105 and the memory device 110 may be operable to support one or more of: modulation schemes to modulate the signals, various pin configurations for communicating the signals, various form factors for physical packaging of the host device 105 and the memory device 110, clock signaling and synchronization between the host device 105 and the memory device 110, timing conventions, or other functions.

The memory device 110 may be operable to store data for the components of the host device 105. In some examples, the memory device 110 (e.g., operating as a secondary-type device to the host device 105, operating as a dependent-type device to the host device 105) may respond to and execute commands provided by the host device 105 through the external memory controller 120. Such commands may include one or more of a write command for a write operation, a read command for a read operation, a refresh command for a refresh operation, or other commands.

The host device 105 may include one or more of an external memory controller 120, a processor 125, a basic input/output system (BIOS) component 130, or other components such as one or more peripheral components or one or more input/output controllers. The components of the host device 105 may be coupled with one another using a bus 135.

The processor 125 may be operable to provide functionality (e.g., control functionality) for the system 100 or the host device 105. The processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination of these components. In such examples, the processor 125 may be an example of a central processing unit (CPU), a graphics processing unit (GPU), a general purpose GPU (GPGPU), or an SoC, among other examples. In some examples, the external memory controller 120 may be implemented by or be a part of the processor 125.

The BIOS component 130 may be a software component that includes a BIOS operated as firmware, which may initialize and run various hardware components of the system 100 or the host device 105. The BIOS component 130 may also manage data flow between the processor 125 and the various components of the system 100 or the host device 105. The BIOS component 130 may include instructions (e.g., a program, software) stored in one or more of read-only memory (ROM), flash memory, or other non-volatile memory.

The memory device 110 may include a device memory controller 155 and one or more memory dies 160 (e.g., memory chips) to support a capacity (e.g., a desired capacity, a specified capacity) for data storage. Each memory die 160 (e.g., memory die 160-a, memory die 160-b, memory die 160-N) may include a local memory controller 165 (e.g., local memory controller 165-a, local memory controller 165-b, local memory controller 165-N) and a memory array 170 (e.g., memory array 170-a, memory array 170-b, memory array 170-N). A memory array 170 may be a collection (e.g., one or more grids, one or more banks, one or more tiles, one or more sections) of memory cells, with each memory cell being operable to store one or more bits of data. A memory device 110 including two or more memory dies 160 may be referred to as a multi-die memory or a multi-die package or a multi-chip memory or a multi-chip package.

The device memory controller 155 may include components (e.g., circuitry, logic) operable to control operation of the memory device 110. The device memory controller 155 may include hardware, firmware, or instructions that enable the memory device 110 to perform various operations and may be operable to receive, transmit, or execute commands, data, or control information related to the components of the memory device 110. The device memory controller 155 may be operable to communicate with one or more of the external memory controller 120, the one or more memory dies 160, or the processor 125. In some examples, the device memory controller 155 may control operation of the memory device 110 described herein in conjunction with the local memory controller 165 of the memory die 160.

A local memory controller 165 (e.g., local to a memory die 160) may include components (e.g., circuitry, logic) operable to control operation of the memory die 160. In some examples, a local memory controller 165 may be operable to communicate (e.g., receive or transmit data or commands or both) with the device memory controller 155. In some examples, a memory device 110 may not include a device memory controller 155, and a local memory controller 165 or the external memory controller 120 may perform various functions described herein. As such, a local memory controller 165 may be operable to communicate with the device memory controller 155, with other local memory controllers 165, or directly with the external memory controller 120, or the processor 125, or any combination thereof. Examples of components that may be included in the device memory controller 155 or the local memory controllers 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, or various other components operable for supporting described operations of the device memory controller 155 or local memory controller 165 or both.

The external memory controller 120 may be operable to enable communication of information (e.g., data, commands, or both) between components of the system 100 (e.g., between components of the host device 105, such as the processor 125, and the memory device 110). The external memory controller 120 may process (e.g., convert, translate) communications exchanged between the components of the host device 105 and the memory device 110. In some examples, the external memory controller 120, or other component of the system 100 or the host device 105, or its functions described herein, may be implemented by the processor 125. For example, the external memory controller 120 may be hardware, firmware, or software, or some combination thereof implemented by the processor 125 or other component of the system 100 or the host device 105. Although the external memory controller 120 is depicted as being external to the memory device 110, in some examples, the external memory controller 120, or its functions described herein, may be implemented by one or more components of a memory device 110 (e.g., a device memory controller 155, a local memory controller 165) or vice versa.

The components of the host device 105 may exchange information with the memory device 110 using one or more channels 115. The channels 115 may be operable to support communications between the external memory controller 120 and the memory device 110. Each channel 115 may be an example of a transmission medium that carries information between the host device 105 and the memory device 110. Each channel 115 may include one or more signal paths (e.g., a transmission medium, a conductor) between terminals associated with the components of the system 100. A signal path may be an example of a conductive path operable to carry a signal. For example, a channel 115 may be associated with a first terminal (e.g., including one or more pins, including one or more pads) at the host device 105 and a second terminal at the memory device 110. A terminal may be an example of a conductive input or output point of a device of the system 100, and a terminal may be operable to act as part of a channel.

Channels 115 (and associated signal paths and terminals) may be dedicated to communicating one or more types of information. For example, the channels 115 may include one or more command and address (CA) channels 186, one or more clock signal (CK) channels 188, one or more data (DQ) channels 190, one or more other channels 192, or any combination thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols (e.g., signal levels) of a signal may be registered for each clock cycle (e.g., on both a rising edge and a falling edge of a clock signal).

Methods for fabricating aspects of a memory device 110 without unintentionally affecting gate oxides are described herein. In some instances, aspects of the memory device 110 may be formed using a wet etching process. For example, a wet etching process may be used to remove (e.g., etch) one or more materials (e.g., nitrides) when forming wordlines. The wet etching process may include depositing a first resist material and a second resist material to selectively remove (e.g., etch) different portions of the nitride material. Such processes may result in gate oxides of the memory device 110 being relatively uniform in shape, which may improve the overall performance of the memory device 110. Moreover, having uniform gate oxides may mitigate undesirable current loss that may otherwise occur due to having non-uniform gate oxides, and may result in fewer portions (e.g., dice) of the memory device 110 being discarded.

In addition to applicability in memory devices as described herein, techniques for wordline recess formation and resulting structures may be generally implemented to improve the performance (including gaming) of various electronic devices and systems. Some electronic device applications, including gaming and other high-performance applications, may be associated with relatively high processing requirements while also benefitting from relatively quick response times to improve user experience. As such, increasing processing speed, decreasing response times, or otherwise improving the performance electronic devices may be desirable. Implementing the techniques described herein may improve the performance of electronic devices by preventing die loss at a memory device, resulting in an increased useable storage capacity of the memory device, which may decrease processing or latency times, improve response times, or otherwise improve user experience, among other benefits.

FIGS. 2A through 2F show examples of processing steps 200 (e.g., processing steps 200-a through 200-f) that support wordline recess formation and resulting structures in accordance with examples as disclosed herein. The processing steps 200 may illustrate aspects of a sequence of manufacturing operations for fabricating aspects of a memory architecture, which may be implemented by a memory device 110, as described with reference to FIG. 1. For illustrative purposes, aspects of the memory architecture may be described with reference to an x-direction, a y-direction, and a z-direction of the illustrated coordinate system. For example, the processing steps 200 may illustrate various cross-sectional views of a memory architecture in an xz-plane. In some examples, the z-direction may be illustrative of a direction orthogonal to a surface of a substrate (e.g., a surface in an xy-plane, a surface above which components may be formed), and each of the related regions, illustrated by their respective cross section in the xz-plane, may extend for some distance along the y-direction (e.g., into the page).

Although the processing steps 200 illustrate examples of relative dimensions and quantities of various features, aspects of the memory architecture may be implemented with other relative dimensions or quantities of such features in accordance with examples as disclosed herein. In the following description of the processing steps 200, some methods, techniques, processes, and operations may be performed in different orders or at different times. Further, some operations may be left out of the processing steps 200, or other operations may be added to the processing steps 200. The processing steps 200 may illustrate operations associated with performing a wet etch to remove portions of a titanium nitride material 220 above wordline regions 205.

Operations illustrated in and described with reference to FIGS. 2A through 2F may be performed by a manufacturing system, such as a semiconductor fabrication system configured to perform additive operations such as deposition, bonding, or coupling, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 2A illustrates a first processing step 200-a that supports wordline recess formation and resulting structures in accordance with examples as disclosed herein. The first processing step 200-a may illustrate wordline regions 205 (e.g., portions of silicon material) extending along the z-direction. The wordlines regions 205 may include a silicon material 210 (e.g., or other semiconductor material) and an oxide material 215 lining (e.g., with a uniform thickness) the silicon material 210. In some examples, the oxide material 215 may be a gate oxide region (e.g., finger) for wordlines formed during a subsequent operation. In some cases, each wordline region 205 may have a same height 206 (e.g., a fourth height, along the z-direction relative to 201). In other cases, at a portion 202 (e.g., a center region, a first portion), one or more wordline regions 205-a may have a height 206, whereas one or more wordline regions 205-b associated with a portion 203 (e.g., an edge region, a second portion) may have a height 207 (e.g., a fifth height, along the z-direction relative to 201, greater than the height 206). In some such cases, the wordline regions 205 may have different heights based on trenches associated with forming the wordline regions 205 being different depths (e.g., along the z-direction). In some implementations, the one or more wordline regions 205-a may have a different width (e.g., along the x-direction) than the one or more wordline regions 205-b.

The first processing step 200-a may also illustrate a titanium nitride material 220, which may be located at least partially above the wordline regions 205 (e.g., along the z-direction), and surround the wordline regions 205 (e.g., in the x-direction and the y-direction). The first processing step 200-a may further illustrate a silicon material 225 (e.g., a second silicon material 225), which may be a doped silicon-based material located at least partially below the wordline regions 205 and the titanium nitride material 220 (e.g., along the z-direction).

The silicon material 225 may at least partially surround the wordline regions 205 (e.g., in the x-direction and the y-direction) below the titanium nitride material 220 (e.g., along the z-direction). For example, a top surface 226 of the silicon material 225 may contact a bottom surface 221 of the titanium nitride material 220. In some cases, a portion (e.g., a third portion) of the silicon material 225 may have a height 227 (e.g., a third height, along the z-direction relative to 201) and another portion (e.g., a fourth portion) of the silicon material 225 may have a height 228 (e.g., a fourth height, along the z-direction relative to 201), where the height 227 is less than the height 206 of the wordline regions 205, and the height 228 is greater than the height 207 of the wordline regions 205.

The first processing step 200-a may also illustrate a cap 230, where the cap 230 may be a silicon-based material (e.g., titanium, silicon, oxide, nitride, or any combination thereof). In some cases, the cap may protect the titanium nitride material 220 during one or more processing steps. The cap 230 may be located above the titanium nitride material 220 (e.g., along the z-direction) such that a bottom surface 231 of the cap 230 may contact a top surface 222 of the titanium nitride material 220.

In some cases, the first processing step 200-a may include forming the wordlines regions 205 and depositing the titanium nitride material 220, the silicon material 225, and the cap 230. For example, the wordline regions 205 may be formed in the titanium nitride material 220 and the silicon material 225, and the cap may be deposited on the titanium nitride material 220. In another example, the titanium nitride material 220 and the silicon material 225 may be deposited after forming the wordline regions 205, and the cap may be deposited on the titanium nitride material 220.

FIG. 2B illustrates a second processing step 200-b that supports wordline recess formation and resulting structures in accordance with examples as disclosed herein. The second processing step 200-b may illustrate removing the cap 230. The cap 230 may be removed after one or more processing steps (e.g., not shown) or after being deposited above the titanium nitride material 220. In some cases, the cap 230 may be removed by an etching operation, a planarization operation, an exhuming operation, or another removal operation. For example, the cap 230 may be exposed to an exhuming gas (e.g., oxide fluorine gas) for a duration, such that once the duration is satisfied, the cap 230 may be exhumed. The second processing step 200-b may also include planarizing the titanium nitride material 220 after removing the cap 230.

FIG. 2C illustrates a third processing step 200-c that support wordline recess formation and resulting structures in accordance with examples as disclosed herein. The third processing step 200-c may illustrate forming photomasks above the titanium nitride material 220. For example, the third processing step 200-c may include forming (e.g., depositing) a first photomask 235 above the titanium nitride material 220 (e.g., along the z-direction) in the portion 203, such that a bottom surface 236 of the first photomask 235 may contact the top surface 222 of the titanium nitride material 220. The third processing step 200-c may also include forming (e.g., depositing) a second photomask 240 above the first photomask 235 (e.g., along the z-direction), such that a bottom surface 241 of the second photomask 240 may contact a top surface 237 of the first photomask 235.

In some cases, the first photomask 235 and the second photomask 240 may protect the titanium nitride material 220 during an etching operation (e.g., a wet etching operation), such that the titanium nitride material 220 below the first photomask 235 and the second photomask 240 (e.g., along the z-direction, in the portion 203) may not be removed by the etching operation. In some such cases, the titanium nitride material 220 in the portion 202, may be removed by the etching operation. In some examples, the first photomask 235 may include a developable bottom anti-reflective coating (DBARC), and the second photomask 240 may include a photo-resistive material. In some such examples, the second photomask 240 may act as a soft stop and the first photomask 235 may act as a hard stop during the etching operation, such that the second photomask 240 may partially resist the etching operation and the first photomask 235 may fully resist the etching operation.

FIG. 2D illustrates a fourth processing step 200-d that support wordline recess formation and resulting structures in accordance with examples as disclosed herein. The fourth processing step 200-d illustrates etching the titanium nitride material 220 in the portion 202. The etching operation may be a wet etch operation, in which a wet etchant including an organic acid and an oxidizer (e.g., hydrochloric acid, hydrogen peroxide, or a combination thereof) is applied (e.g., for a duration) to the titanium nitride material 220. The wet etchant may be selective to the titanium nitride material 220, such that other materials may not be etched by the etchant. For example, the oxide material 215 may not be affected by the wet etchant. In some such examples, the wet etchant may not unintentionally damage the oxide material 215, resulting in the oxide material 215 having a relatively uniform thickness, which may improve overall performance of a memory device implementing the memory architecture described herein. For instance, having uniform oxide material 215 at a gate oxide region associated with wordlines of the memory architecture may prevent undesirable current loss associated with having non-uniform oxide material 215 at the gate oxide region. In some such instances, the uniform oxide material 215 may result in fewer portions (e.g., dice) of the memory device being discarded. In some cases, the etching operation may not etch the titanium nitride material 220 in the portion 203 based on the first photomask 235 and the second photomask 240 being resistant to the etching operation.

In some examples, the titanium nitride material 220 may be etched to a height 223 (e.g., a first height, along the z-direction relative to 201), where the height 223 may be less than the height 228 of the silicon material 225 and greater than the height 206 of the wordline regions 205 (e.g., wordline regions 205-a). In some implementations, the height 223 may be less than or equal to the height 207 of the wordline regions 205 (e.g., wordline regions 205-b). In other implementations, the height 223 may be greater than the height 207 of the wordline regions 205.

FIG. 2E illustrates a fifth processing step 200-e that supports wordline recess formation and resulting structures in accordance with examples as disclosed herein. The fifth processing step 200-e may illustrate removing the first photomask 235 and the second photomask 240. For example, the fifth processing step 200-e may include removing the second photomask 240 and the first photomask 235, which may be performed serially or in a single processing step. In some cases, the first photomask 235 and the second photomask 240 may be removed by an etching operation, a planarization operation, an exhuming operation, or another removal operation. The fifth processing step 200-e may also include planarizing the titanium nitride material 220 in the portion 203 after removing the first photomask 235 and the second photomask 240.

FIG. 2F illustrates a sixth processing step 200-f that supports wordline recess formation and resulting structures in accordance with examples as disclosed herein. The sixth processing step 200-f may illustrate a second etching operation. For example, the sixth processing step 200-f may include etching the titanium nitride material 220. The etching operation may be a wet etching operation (e.g., a second wet etching operation), in which a wet etchant is applied (e.g., for a duration) to the titanium nitride material 220. In some examples, the wet etchant may be a same wet etchant or a different wet etchant as used in the fourth processing step 200-d. The wet etchant may include an organic acid and an oxidizer (e.g., hydrochloric acid, hydrogen peroxide, or a combination thereof) and may be selective to the titanium nitride material 220, such that other materials may not be etched by the wet etchant. For example, the oxide material 215 may not be affected by the wet etchant. In some cases, the etching operation may not etch the silicon material 225 based on the silicon material 225 being resistant to the etching operation.

In some examples, the titanium nitride material 220 in the portion 203 may be etched to a height 224 (e.g., a second height, along the z-direction relative to 201), where the height 224 may be greater than the height 207 of the wordline regions 205 (e.g., the wordline regions 205-b). In some examples, the titanium nitride material 220 in the portion 202 may be etched to another height 223 (e.g., a first height, along the z-direction relative to 201), such that the prior height 223 may be decreased, but may be greater than the height 206 of the wordline regions 205. In some implementations, the height 223 may be less than the height 207 of the wordline regions 205. In some examples, the height 224 may be less than the height 228 of the silicon material 225 and greater than the height 223 of the titanium nitride material.

The process described herein with reference to FIGS. 2A through 2F may include performing wet etch operations to remove portions of the titanium nitride material 220 above wordline regions 205 by applying a wet etchant (e.g., hydrochloric acid, hydrogen peroxide, or a combination thereof) that is selective to the titanium nitride material 220, such that the wet etchant may not unintentionally damage the oxide material 215 lining the wordline regions 205. Further, the process may include forming the first photomask 235 and the second photomask 240 which may be resistant to the wet etchant to further support selective removal of the titanium nitride material 220 during the wet etch operations. Such processes described herein may result in oxide material 215 of the memory device being relatively uniform in shape, which may improve the device's overall performance. Moreover, having uniform oxide material 215 may mitigate undesirable current loss that may otherwise occur due to having non-uniform oxide material 215, and may result in fewer portions (e.g., dice) of the memory device being discarded.

FIG. 3 shows a flowchart illustrating a method 300 that supports wordline recess formation and resulting structures in accordance with examples as disclosed herein. The operations of method 300 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 305, the method may include forming a titanium nitride material above one or more portions of a first silicon material, each portion of the one or more portions of the first silicon material including an oxide liner. The operations of 305 may be performed in accordance with examples as disclosed herein.

At 310, the method may include forming a first photomask and a second photomask above a first portion of the titanium nitride material. The operations of 310 may be performed in accordance with examples as disclosed herein.

At 315, the method may include removing, via a wet etch operation and based at least in part on forming the first photomask and the second photomask, a second portion of the titanium nitride material that extends to a first depth above the respective oxide liners of the one or more portions of the first silicon material. The operations of 315 may be performed in accordance with examples as disclosed herein.

At 320, the method may include removing the first photomask and the second photomask based at least in part on removing the second portion of the titanium nitride material. The operations of 320 may be performed in accordance with examples as disclosed herein.

In some examples, an apparatus (e.g., a manufacturing system) as described herein may perform a method or methods, such as the method 300. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for forming a titanium nitride material above one or more portions of a first silicon material, each portion of the one or more portions of the first silicon material including an oxide liner; forming a first photomask and a second photomask above a first portion of the titanium nitride material; removing, via a wet etch operation and based at least in part on forming the first photomask and the second photomask, a second portion of the titanium nitride material that extends to a first depth above the respective oxide liners of the one or more portions of the first silicon material; and removing the first photomask and the second photomask based at least in part on removing the second portion of the titanium nitride material.
Aspect 2: The method or apparatus of aspect 1, further including operations, features, circuitry, logic, means, or instructions, or any combination thereof for removing, via a second wet etch operation, a third portion of the titanium nitride material based at least in part on removing the first photomask and the second photomask, where the first portion of the titanium nitride material includes the third portion of the titanium nitride material, and where the third portion of the titanium nitride material extends to a second depth above the respective oxide liners of the one or more portions of the silicon material.
Aspect 3: The method or apparatus of aspect 2, where the first depth is different than the second depth.
Aspect 4: The method or apparatus of any of aspects 2 through 3, further including operations, features, circuitry, logic, means, or instructions, or any combination thereof for forming a second silicon material before forming the titanium nitride material, where a top surface of the second silicon material is in contact with a bottom surface of the titanium nitride material, and where the second silicon material is resistant to a first etchant associated with the second wet etch operation.
Aspect 5: The method or apparatus of aspect 4, where the first photomask and the second photomask are formed above the doped silicon material.
Aspect 6: The method or apparatus of any of aspects 1 through 5, further including operations, features, circuitry, logic, means, or instructions, or any combination thereof for forming a cap based at least in part on forming the titanium nitride material, where a top surface of the titanium nitride material is in contact with a bottom surface of the cap and removing the cap before forming the first photomask and the second photomask above the first portion of the titanium nitride material.
Aspect 7: The method or apparatus of any of aspects 1 through 6, where forming the first photomask and the second photomask includes operations, features, circuitry, logic, means, or instructions, or any combination thereof for forming the first photomask above the first portion of the titanium nitride material, where a top surface of the titanium nitride material is in contact with a bottom surface of the first photomask and forming the second photomask above the first photomask, where a top surface of the first photomask is in contact with a bottom surface of the second photomask.
Aspect 8: The method or apparatus of any of aspects 1 through 7, where removing, via the wet etch operation, the second portion of the titanium nitride material includes operations, features, circuitry, logic, means, or instructions, or any combination thereof for exposing the titanium nitride material to an etchant, where the first photomask and the second photomask are resistant to the etchant.
Aspect 9: The method or apparatus of aspect 8, where removing, via the wet etch operation, the second portion of the titanium nitride material includes operations, features, circuitry, logic, means, or instructions, or any combination thereof for refraining from removing the first photomask and the second photomask, where the first photomask and the second photomask are resistant to the etchant.
Aspect 10: The method or apparatus of any of aspects 1 through 8, where the one or more portions of the silicon material are associated with respective wordline regions.
Aspect 11: The method or apparatus of any of aspects 1 through 10, where a first portion of the silicon material includes a first height and is located below the first portion of the titanium nitride material, and a second portion of the silicon material includes a second height and is located below the second portion of the titanium nitride material.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 12: An apparatus, including: a titanium nitride material including a first portion having a first height and a second portion having a second height; a first silicon material including a third portion having a third height and a fourth portion having a fourth height; and one or more portions of a second silicon material extending through a fifth portion of the first silicon material and a sixth portion of the titanium nitride material, where each portion of the one or more portions of the second silicon material includes an oxide liner having a uniform thickness.
Aspect 13: The apparatus of aspect 12, where a top surface of the third portion of the first silicon material is in contact with a bottom surface of the first portion and the second portion of the titanium nitride material, and a top surface of the fourth portion of the first silicon material extends above a top surface of the second portion of the titanium nitride material, and where the fourth portion of the first silicon material includes a third height that is greater than the first height and the second height.
Aspect 14: The apparatus of any of aspects 12 through 13, further including: a first portion of the second silicon material including a fourth height and located below the first portion of the titanium nitride material; and a second portion of the second silicon material including a fifth height and located below the second portion of the titanium nitride material, where the fifth height is greater than the fourth height.
Aspect 15: The apparatus of aspect 14, further including: a plurality of first portions of the second silicon material, where each portion of the plurality of first portions includes the fourth height and is located below the first portion of the titanium nitride material.
Aspect 16: The apparatus of any of aspects 12 through 15, where the one or more portions of the second silicon material are associated with respective wordline regions.
Aspect 17: The apparatus of any of aspects 12 through 16, where the fourth portion of the first silicon material is adjacent to a first sidewall of the second portion of the titanium nitride material.

An apparatus is described. The following provides an overview of aspects of the apparatus as described herein:
Aspect 18: An apparatus, including: a first silicon material; a titanium nitride material located above the first silicon material; and one or more portions of a second silicon material extending through a portion of the first silicon material and the titanium nitride material, where each portion of the one or more portions of the second silicon material including an oxide liner having a uniform thickness, and where the titanium nitride material is formed by: forming a first photomask and a second photomask above a first portion of the titanium nitride material; removing, via a wet etch operation and based at least in part on forming the first photomask and the second photomask, a second portion of the titanium nitride material that extends to a first depth above the respective oxide liners of the one or more portions of the second silicon material; and removing the first photomask and the second photomask based at least in part on removing the second portion of the titanium nitride material.
Aspect 19: The apparatus of aspect 18, where the titanium nitride material is further formed by removing, via a second wet etch operation, a third portion of the titanium nitride material based at least in part on removing the first photomask and the second photomask, where the first portion of the titanium nitride material comprises the third portion of the titanium nitride material, and wherein the third portion of the titanium nitride material extends to a second depth above the respective oxide liners of the one or more portions of the second silicon material.
Aspect 20: The apparatus of aspects 18 through 19, where the one or more portions of the second silicon material are associated with respective wordline regions.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
forming a titanium nitride material above one or more portions of a first silicon material, each portion of the one or more portions of the first silicon material comprising an oxide liner;
forming a first photomask and a second photomask above a first portion of the titanium nitride material;
removing, via a wet etch operation and based at least in part on forming the first photomask and the second photomask, a second portion of the titanium nitride material that extends to a first depth above the respective oxide liners of the one or more portions of the first silicon material; and
removing the first photomask and the second photomask based at least in part on removing the second portion of the titanium nitride material.

2. The method of claim 1, further comprising:
removing, via a second wet etch operation, a third portion of the titanium nitride material based at least in part on removing the first photomask and the second photomask, wherein the first portion of the titanium nitride material comprises the third portion of the titanium nitride material, and wherein the third portion of the titanium nitride material extends to a second depth above the respective oxide liners of the one or more portions of the first silicon material.

3. The method of claim 2, wherein the first depth is different than the second depth.

4. The method of claim 2, further comprising:
forming a second silicon material before forming the titanium nitride material, wherein a top surface of the second silicon material is in contact with a bottom surface of the titanium nitride material, and wherein the second silicon material is resistant to a first etchant associated with the second wet etch operation.

5. The method of claim 4, wherein the first photomask and the second photomask are formed above the second silicon material.

6. The method of claim 1, further comprising:
forming a cap based at least in part on forming the titanium nitride material, wherein a top surface of the titanium nitride material is in contact with a bottom surface of the cap; and
removing the cap before forming the first photomask and the second photomask above the first portion of the titanium nitride material.

7. The method of claim 1, wherein forming the first photomask and the second photomask comprises:
forming the first photomask above the first portion of the titanium nitride material, wherein a top surface of the titanium nitride material is in contact with a bottom surface of the first photomask; and
forming the second photomask above the first photomask, wherein a top surface of the first photomask is in contact with a bottom surface of the second photomask.

8. The method of claim 1, wherein removing, via the wet etch operation, the second portion of the titanium nitride material comprises:
exposing the titanium nitride material to an etchant, wherein the first photomask and the second photomask are resistant to the etchant.

9. The method of claim 8, wherein removing, via the wet etch operation, the second portion of the titanium nitride material comprises:
refraining from removing the first photomask and the second photomask, wherein the first photomask and the second photomask are resistant to the etchant.

10. The method of claim 1, wherein the one or more portions of the first silicon material are associated with respective wordline regions.

11. The method of claim 1, wherein a first portion of the first silicon material comprises a first height and is located below the first portion of the titanium nitride material, and a second portion of the first silicon material comprises a second height and is located below the second portion of the titanium nitride material.

12. An apparatus, comprising:
a titanium nitride material comprising a first portion having a first height and a second portion having a second height;
a first silicon material comprising a third portion having a third height and a fourth portion having a fourth height; and
one or more portions of a second silicon material extending through a fifth portion of the first silicon material and a sixth portion of the titanium nitride material, wherein each portion of the one or more portions of the second silicon material comprises an oxide liner having a uniform thickness.

13. The apparatus of claim 12, wherein a top surface of the third portion of the first silicon material is in contact with a bottom surface of the first portion and the second portion of the titanium nitride material, and a top surface of the fourth portion of the first silicon material extends above a top surface of the second portion of the titanium nitride material, and wherein the fourth portion of the first silicon material comprises a third height that is greater than the first height and the second height.

14. The apparatus of claim 12, further comprising:
a first portion of the second silicon material comprising a fourth height and located below the first portion of the titanium nitride material; and
a second portion of the second silicon material comprising a fifth height and located below the second portion of the titanium nitride material, wherein the fifth height is greater than the fourth height.

15. The apparatus of claim 14, further comprising:
a plurality of first portions of the second silicon material, wherein each portion of the plurality of first portions comprises the fourth height and is located below the first portion of the titanium nitride material.

16. The apparatus of claim 12, wherein the one or more portions of the second silicon material are associated with respective wordline regions.

17. The apparatus of claim 12, wherein the fourth portion of the first silicon material is adjacent to a first sidewall of the second portion of the titanium nitride material.

18. An apparatus, comprising:
a first silicon material;
a titanium nitride material located above the first silicon material; and
one or more portions of a second silicon material extending through a portion of the first silicon material and the titanium nitride material, wherein each portion of the one or more portions of the second silicon material comprising an oxide liner having a uniform thickness, and wherein the titanium nitride material is formed by:
forming a first photomask and a second photomask above a first portion of the titanium nitride material;
removing, via a wet etch operation and based at least in part on forming the first photomask and the second photomask, a second portion of the titanium nitride material that extends to a first depth above the respective oxide liners of the one or more portions of the second silicon material; and
removing the first photomask and the second photomask based at least in part on removing the second portion of the titanium nitride material.

19. The apparatus of claim 18, wherein the titanium nitride material is further formed by:
removing, via a second wet etch operation, a third portion of the titanium nitride material based at least in part on removing the first photomask and the second photomask, wherein the first portion of the titanium nitride material comprises the third portion of the titanium nitride material, and wherein the third portion of the titanium nitride material extends to a second depth above the respective oxide liners of the one or more portions of the second silicon material.

20. The apparatus of claim 18, wherein the one or more portions of the second silicon material are associated with respective wordline regions.
